(19) United States
(12) Patent Application Publication
(10) Pub. No.: US 2012/0009765 A1
(43) Pub. Date: Jan. 12, 2012

(54) COMPARTMENTALIZED CHAMBER

(75) Inventor: Donald J.K. Olgado, Palo Alto, CA (US)

(73) Assignee: APPLIED MATERIALS, INC., Santa Clara, CA (US)

(21) Appl. No.: 13/181,451

(22) Filed: Jul. 12, 2011

Related U.S. Application Data
(60) Provisional application No. 61/363,555, filed on Jul. 12, 2010.

(51) Int. Cl. H01L 21/20; C23C 16/455

(52) U.S. Cl. 438/478; 118/719; 257/E21.09

(57) ABSTRACT

Embodiments of the present invention generally relate to apparatus for improving processing uniformity and reducing needs of chamber cleaning. Particularly, embodiments of the present invention relate to a processing chamber having a loading compartment and a processing compartment in substantial fluid isolation and methods of depositing films in the processing chamber.

### CROSS-REFERENCE TO RELATED APPLICATIONS

This application claims benefit of U.S. provisional patent application Ser. No. 61/363,555, filed Jul. 12, 2010, which is herein incorporated by reference.

### BACKGROUND OF THE INVENTION

1. Field of the Invention

Embodiments of the present invention generally relate to apparatus for semiconductor processing. More particularly, embodiments of the present invention relate to a processing chamber having a loading compartment and a processing compartment.

2. Description of the Related Art

Semiconductor processing chambers provide processing environments for one or more processes, such as etch or deposition, in fabrication of devices on substrates. Most semiconductor processing chambers have several common features. For example, most processing chambers have a chamber enclosure in which the substrate is received for processing, a gas inlet for providing one or more processing gases to the chamber enclosure, an exhaust coupled to a vacuum pump for evacuating the chamber enclosure and driving gas flow in the chamber enclosure, a substrate support member disposed in the chamber enclosure for supporting the substrate during processing, and a slit valve opening through chamber walls to allow the substrates in and out of the chamber enclosure.

Generally, one or more processing gases are flown into a chamber enclosure of a processing chamber during processing. It is desirable for the substrate surface to have uniform exposure to the processing gases. However, the slit valve opening, usually located to one side of the processing chamber, usually compromises the symmetry of the chamber enclosure and makes the gas flow in the chamber enclosure non-uniform.

Additionally, processing gases flowing through the chamber enclosure may deposit undesired films on inner surfaces of the processing chamber. The films formed on the inner surfaces are friable and, if left in place, can form contaminant particles in the chamber enclosure causing defects on the substrate being processed. Therefore, periodic and routine chamber cleaning is usually necessary. However, chamber cleaning results in chamber down time which increases cost of ownership.

Therefore, there is a need for a processing chamber that improves processing uniformity and reduces the needs for chamber cleaning.

### SUMMARY OF THE INVENTION

Embodiments of the present invention generally relate to apparatus for improving processing uniformity and reducing the needs for chamber cleaning. Particularly, embodiments of the present invention relate to a processing chamber having a loading compartment and a processing compartment.

One embodiment provides an apparatus comprising a lower chamber body surrounding a loading compartment of a chamber enclosure, wherein a slit valve door opening is formed through the lower chamber body. The apparatus further comprises an upper chamber body disposed over the lower chamber body, wherein the upper chamber body surrounds a processing compartment of the chamber enclosure, two or more exhaust channels are formed through the upper chamber body, and the two or more exhaust channels are evenly distributed along the upper chamber body. The apparatus also comprises a showerhead assembly disposed over the upper chamber body, and a substrate support disposed in the chamber enclosure, wherein the processing compartment has a lower inner diameter smaller than an outer diameter of the substrate support. The substrate support is movable between a lower substrate loading and unloading position and an upper substrate processing position, and the substrate support is configured and positionable to restrict or substantially prevent fluid communication between the loading compartment and the processing compartment at the upper processing position.

Another embodiment provides an apparatus for performing metal organic chemical vapor deposition (MOCVD). The apparatus comprises a lower dome transparent to thermal energy, a lower chamber assembly disposed over the lower dome, wherein the lower chamber assembly has a slit valve opening formed therethrough, and an upper chamber assembly disposed over the lower chamber assembly, wherein a symmetrical exhaust path is formed through the upper chamber assembly. The apparatus further comprises a showerhead assembly disposed over the upper chamber assembly, wherein the showerhead assembly, the lower chamber assembly, the upper chamber assembly and the lower dome define a chamber enclosure. The apparatus also comprises a heating assembly disposed outside the chamber enclosure and configured to transmit thermal energy to the chamber enclosure through the lower dome, and a substrate support movably disposed in the chamber enclosure. The upper chamber assembly has a lower inner diameter smaller than an outer diameter of the substrate support. The substrate support is movable between a lower loading position and an upper processing position, and the substrate support separates the chamber enclosure into a processing compartment and a loading compartment at the upper processing position.

Yet another embodiment of the present invention provides a processing kit comprising an upper liner assembly defining a symmetrical fluid path, and a lower liner having a slit valve door opening formed therethrough.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a sectional view of a processing chamber in accordance with one embodiment of the present invention.

FIG. 1B is a sectional view of the processing chamber of FIG. 1A in a processing position.

FIG. 2 is an exploded sectional view of an upper chamber assembly and a lower chamber assembly in accordance with one embodiment of the present invention.

FIG. 3A is a partial enlarged view of one embodiment of a liner assembly in a processing compartment of the processing chamber shown in FIG. 1B.

FIG. 3B is a partial enlarged view of one embodiment of a liner assembly in a processing compartment of the processing chamber shown in FIG. 1B.

FIG. 3C is a partial enlarged view of one embodiment of a liner assembly in a processing compartment of the processing chamber shown in FIG. 1B.

FIG. 4 is a schematic top view showing a gas flow path of a processing chamber in accordance with one embodiment of the present invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present invention generally relate to apparatus for improving processing uniformity and reducing needs of chamber cleaning. Particularly, embodiments of the present invention relate to a processing chamber having a loading compartment and a processing compartment. The loading compartment and the processing compartment are fluidly isolated during processing to minimize or prevent deposition in the loading compartment.

Embodiments of the present invention provide a processing chamber which includes an upper chamber assembly disposed over a lower chamber assembly. The lower chamber assembly has a slit valve opening formed therethrough to allow substrate transfer. The upper chamber assembly includes a portion having a larger diameter than the lower chamber assembly. Exhaust paths for processing gases are formed in the upper chamber assembly. A substrate support disposed in the processing chamber can move between a lower loading position to load and unload a substrate through a slit valve and an upper substrate processing position. While in the upper substrate processing position, the substrate support and a cover ring disposed in the upper chamber assembly isolate an upper chamber volume from a lower chamber volume in the processing chamber. The upper chamber volume including symmetrical paths for processing gases forms a processing compartment. The lower chamber volume surrounded by the slit valve opening forms a loading compartment. The isolation between the processing compartment and the loading compartment improves processing uniformity and reduces contamination in the loading compartment.

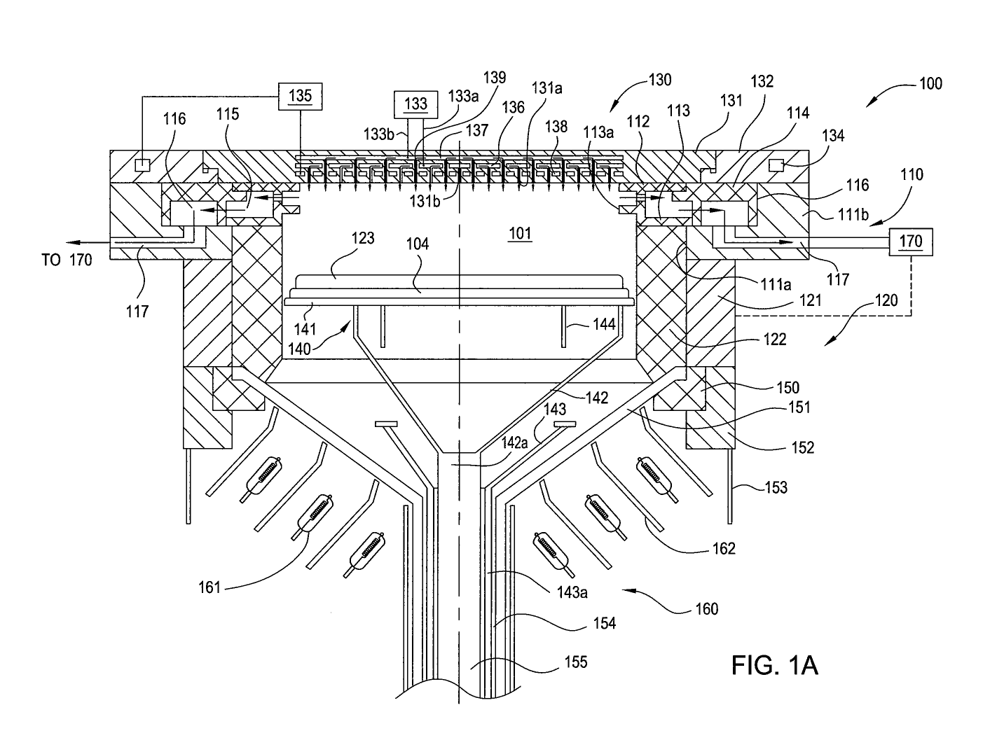

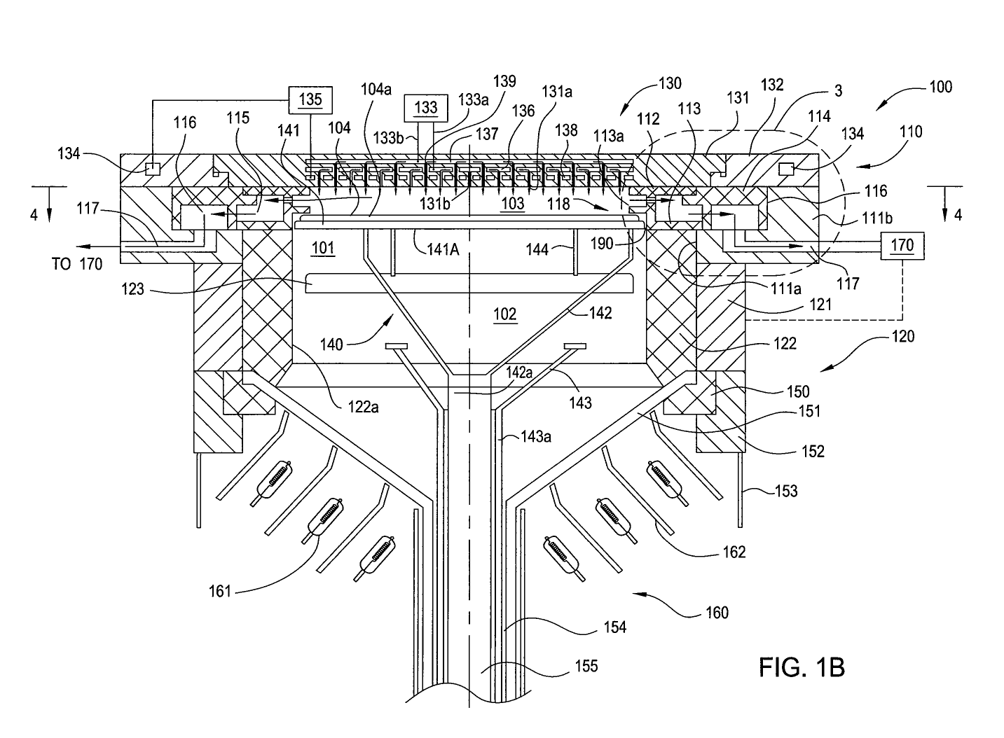

FIG. 1A is a sectional view of a processing chamber 100 in accordance with one embodiment of the present invention. FIG. 1B is a sectional view of the processing chamber 100 in a processing position. In one example, the processing chamber 100 may be a metal organic chemical vapor deposition (MOCVD) chamber configured to perform a thermal based vapor deposition process. For example, the processing chamber 100 may be used to form metal nitride films by MOCVD processes in the course of manufacturing nitride compound semiconductor devices, such as light emitting diodes (LEDs) and laser diodes (LDs).

### General Structure

The processing chamber 100 comprises a lower chamber assembly 120 and an upper chamber assembly 110 disposed above the lower chamber assembly 120. The processing chamber 100 further comprises a showerhead assembly 130 disposed over the upper chamber assembly 110 and a lower dome 151 disposed under the lower chamber assembly 120. The showerhead assembly 130, the upper chamber assembly 110, the lower chamber assembly 120, and the lower dome 151 define a chamber enclosure 101. A heating assembly 160 is disposed below the lower dome 151 and is configured to provide thermal energy into the chamber enclosure 101 through the lower dome 151.

A substrate support assembly 140 is movably disposed in the chamber enclosure 101. The substrate support assembly 140 may move vertically between a lower substrate loading/unloading position (shown in FIG. 1A) and an upper substrate processing position (shown in FIG. 1B).

### The Showerhead Assembly

The showerhead assembly 130 may comprise a showerhead-supporting ring 132 coupled to the upper chamber assembly 110 and a showerhead plate 131 disposed inside the circumference of showerhead-supporting ring 132. The showerhead plate 131, shown in FIG. 1A as one piece for simplicity, may comprise two or more plates stacked together to form independent pathways 136, 137 for two or more processing gases and cooling channels (such as heat exchanging channel 138). Each independent pathway 136, 137 has a plurality of apertures 131b opening to the chamber enclosure 101 on a showerhead surface 131a. The plurality of apertures 131b for each independent path may be evenly distributed across the showerhead surface 131a. The showerhead plate 131 may be formed from a metal, such as 316L stainless steel, INCONEL®, HASTELLOY®, electroless nickel plated aluminum, pure nickel, and other metals and alloys resistant to chemical attack, or even quartz.

The showerhead plate 131 receives processing gases from a gas distribution system 133 (shown schematically) via two or more gas supply lines 133a, 133b. The gas distribution system 133 may comprise sources for precursors, carrier gas, and purge gas. The gas distribution system 133 may also comprise one or more remote plasma sources. The processing gases are distributed from the gas distribution system 133 to the processing compartment 103 (shown in FIG. 1B) through the showerhead plate 131.

In one configuration, the gas distribution system 133 includes sources of process gases for deposition of various metal nitride films, including gallium nitride (GaN), aluminum nitride (AlN), indium nitride (InN), and compound films, such as AlGaN and InGaN. The gas distribution system 133 may also comprise sources for dopant gases such as silane (SiH₄) or disilane (Si₂H₆) gases for silicon doping, and Bis(cyclopentadienyl) magnesium (Cp₂Mg or (C₅H₅)₂Mg) for magnesium doping. The gas distribution system 133 may also comprise sources for non-reactive gases, such as hydrogen (H₂), nitrogen (N₂), helium (He), argon (Ar) or other gases and combinations thereof.

The showerhead plate 131 includes a heat exchanging channel 138 through which gas conduits 139 in the showerhead plate 131 extend to control the temperature of the gases or vapor delivered therethrough and into the chamber enclosure 101 of the processing chamber 100. The showerhead-supporting ring 132 may also include a heat exchanging channel 134 for temperature control. The heat exchanging channels 134, 138 may be connected to a heat exchanger 135 (shown schematically).

Suitable heat exchanging fluids include water, water-based ethylene glycol mixtures, a perfluoropolyether (e.g., Galden® fluid), oil-based thermal transfer fluids, liquid metals (such as gallium or gallium alloy) or similar fluids. The heat exchanging fluid may be circulated through the heat exchanger 135 to raise or lower the temperature of the heat exchanging fluid as required to maintain the temperature of the showerhead assembly 130 within a desired temperature range.

In one embodiment, the heat exchanging fluid is maintained within a temperature range of about 20° C. to about 120° C. for a MOCVD process. In another embodiment, the heat exchanging fluid may be maintained within a temperature range of about 100° C. to about 350° C. In yet another embodiment, the heat exchanging fluid may be maintained at a temperature of greater than 350° C. The heat exchanging fluid may also be heated above its boiling point so that the showerhead assembly 130 may be maintained at higher temperatures using readily available heat exchanging fluids.

### Heating Assembly

The upper chamber assembly 110 is stacked on the lower chamber assembly 120. The lower chamber assembly 120 is supported by a base member 152, which may be fixed to a foundation 153 or other fixed support. The lower dome 151 is mounted on, supported by the base member 152. A thermal insulator 150 may be disposed between the lower dome 151 and the base member 152. The lower liner 122 may be supported by the lower dome 151.

The heating assembly 160 may comprise a plurality of lamps 161 disposed below the lower dome 151, and reflectors 162 configured to control thermal exposure to the chamber enclosure 101. In one embodiment, the plurality of lamps 161 may be arranged in concentric rings under the lower dome 151.

The lower dome 151 may be made of transparent material, such as high-purity quartz, to allow light from the heating assembly 160 to pass through for radiant heating of the substrates. The lower dome 151 has a central opening 154 to accommodate a moving portion of the substrate support assembly 140.

### Substrate Support Assembly

The substrate support assembly 140 comprises a substrate support 141 disposed on a supporting shaft 142a through a plurality of supporting fingers 142 circumferentially spaced about, and connecting the supporting shaft 142a and the substrate support 141. The supporting shaft 142a is disposed through the central opening 154 of the lower dome 151. The supporting shaft 142a may rotate about a central axis 155 and move vertically along the central axis 155 to move the substrate with respect to the slit valve door 123 and showerhead assembly 130, and to rotate the substrate support 141 and the substrate carrier 104 during substrate processing and, if required, substrate loading and unloading. Three or more lifting pins 144 are movably disposed on the substrate support 141. A pin lifting shaft 143a is configured to move the lifting pins 144 up and down relative to the substrate support 141. When lifted, the lifting pins 144 can receive the substrate carrier 104 from a transfer mechanism or lift the substrate carrier 104 from the substrate support 141. In one embodiment, the lifting pins 144 may lift one or more substrates directly from the substrate support 141 and substrate carrier 104 to enable direct transfer of substrates with a transfer mechanism, such as an outside robot.

To position the substrate support 141 for substrate processing, the substrate support 141 moves vertically between a lower loading position shown in FIG. 1A and an upper substrate processing position shown in FIG. 1B. In the upper substrate processing position, a barrier formed by the substrate support 141 and a liner in the upper chamber assembly 110 separate the chamber enclosure 101 into two compartments with a clearance gap 190 therebetween being the only conductance path between a process region of the processing chamber 100 and the lower portion of the chamber including the slit valve door 123.

In one embodiment, while the substrate support 141 is in the upper substrate processing position, the distance from the showerhead surface 131a to a substrate carrier 104 disposed on the substrate support assembly 140 may range from about 4 mm to about 41 mm.

### Upper and Lower Chamber Assemblies

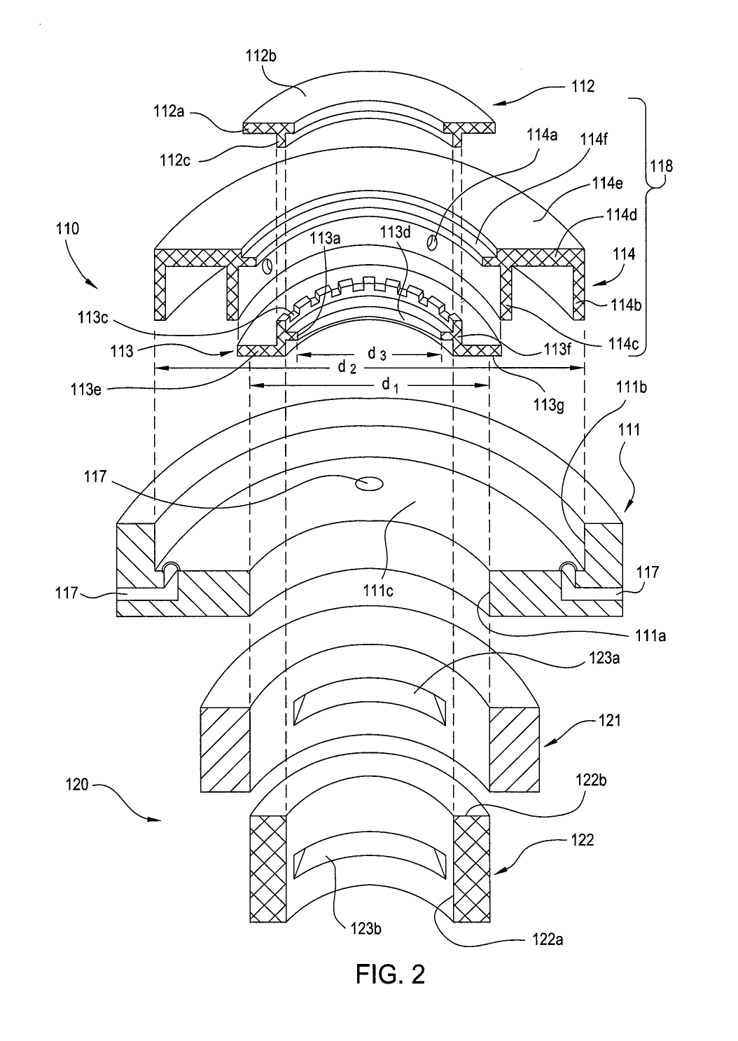

The lower chamber assembly 120 and the upper chamber assembly 110 provide outer structures for the chamber enclosure 101. FIG. 2 is an exploded sectional view of the upper chamber assembly 110 and the lower chamber assembly 120.

The upper chamber assembly 110 comprises an upper chamber body 111 and an upper liner assembly 118 (shown in FIG. 1B) disposed inside the upper chamber body 111. The lower chamber assembly 120 comprises a lower chamber body 121 and a lower liner 122. The upper chamber body 111 is stacked over the lower chamber body 121. The upper chamber body 111 and the lower chamber body 121 form an outer structure for the processing chamber 100. The upper liner assembly 118 and the lower liner 122 line the upper and lower chamber bodies 111, 121 to prevent processing gases from directly contacting the chamber bodies 111, 121.

The upper chamber body 111 is a circular annulus or ring having a radial ledge or step 111c bounded by an upper inner wall 111b and a lower inner wall 111a, each of which extend therefrom in opposed directions. The upper inner wall 111b has an upper inner diameter d2. The lower inner wall 111a has a lower inner diameter d1. The upper inner diameter d2 is greater than the lower inner diameter d1.

A plurality of exhaust channels 117 are symmetrically formed about the circumference of, and through the upper chamber body 111. As shown in FIG. 1A, each of the plurality of exhaust channels 117 is adapted to connect with a vacuum pump 170 for exhausting the chamber enclosure 101. The exhaust channels 117 are formed in symmetrical locations to enable symmetrical pumping, thus increasing processing uniformity. Even though the upper chamber body 111 has four exhaust channels 117 formed 90° apart in the exemplary embodiment, different numbers of exhaust channels 117 can be applied as long as the exhaust channels 117 are evenly distributed along the upper chamber body 111. In another embodiment, the upper chamber body 111 has two exhaust channels 117 formed 180° apart from one another.

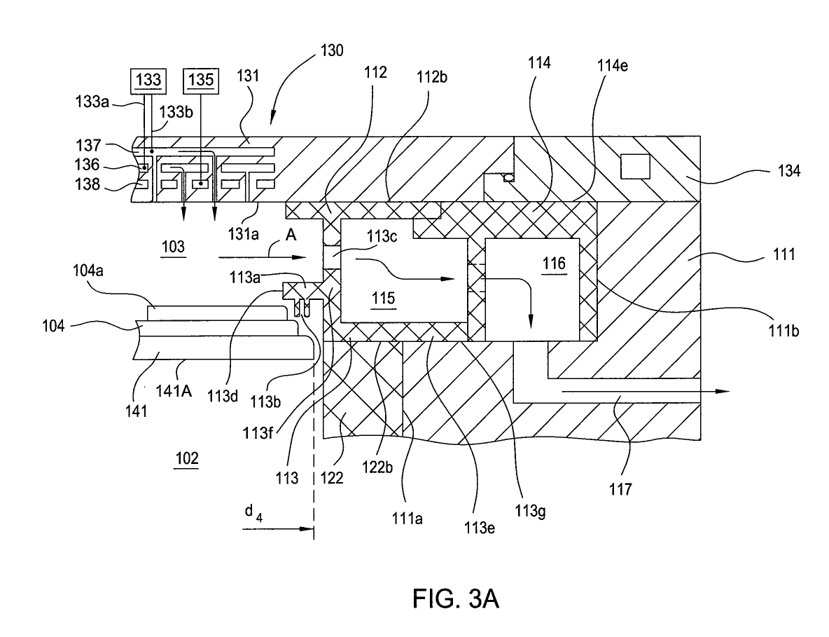

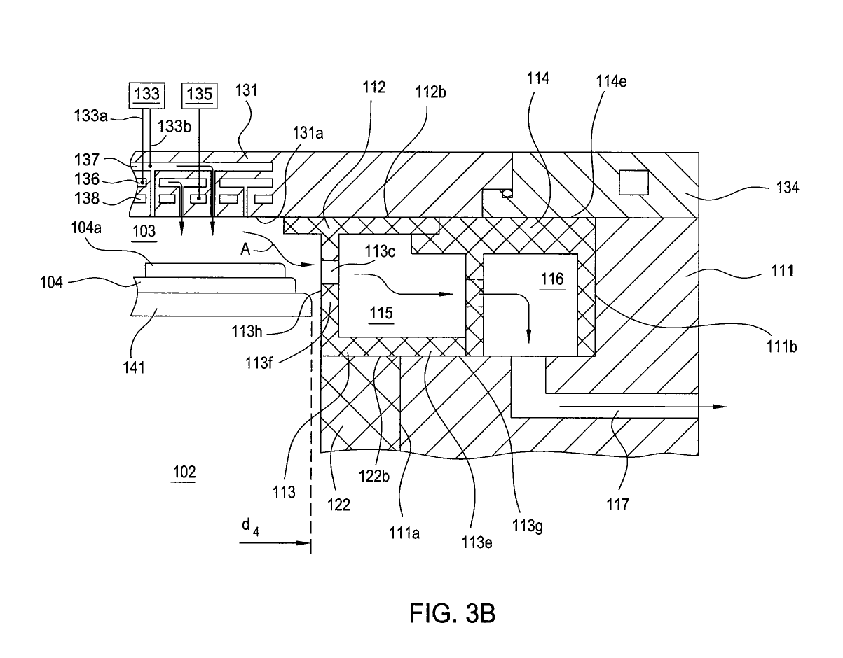

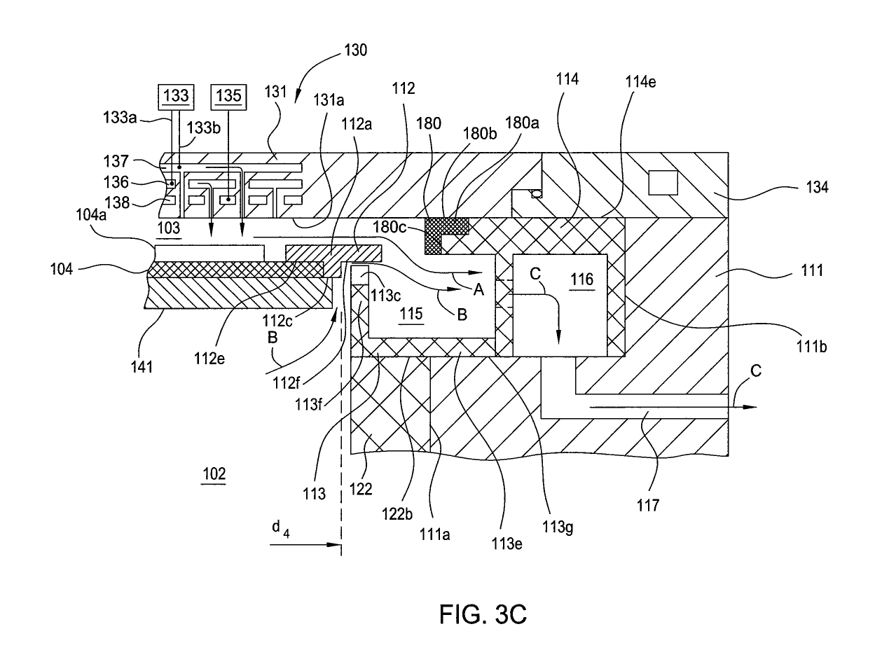

The upper liner assembly 118 is disposed between the step 111c of the upper chamber body 111 and the showerhead surface 131a of the showerhead assembly 130. FIG. 3A illustrates the upper liner assembly 118 in relation to the showerhead assembly 130 and the upper chamber body 111.

The upper liner assembly 118 forms a ring shaped structure formed from materials with low thermal conductivity. The ring shaped structure is designed to cover inner surfaces of the processing chamber 100, provide thermal insulation for the upper chamber body 111, and define flow paths for the processing gases.

In the exemplary embodiment described with the processing chamber 100, the upper liner assembly 118 comprises three liner rings: a showerhead liner 112, a cover ring 113, and an exhaust ring 114. However, persons skilled in the art may modify the upper liner assembly 118 according to specific design requirement, or for convenience of manufacturing.

As shown in FIG. 2, the exhaust ring 114 has an annular body 114d and two concentric annular walls 114b, 114c extending downward from the annular body 114d. The exhaust ring 114 has an outer diameter that closely but not precisely, matches the upper inner diameter d2 of the upper chamber body 111 so that the annular wall 114b protects the upper inner wall 111b of the upper chamber body 111 but is still removable therefrom for servicing and assembly. The annular body 114d has a planar upper surface 114e configured to contact and shield the perimeter of showerhead surface 131a as shown in FIG. 3A. The exhaust ring 114 sits on step 111c of upper chamber body 111, such that the annular body 114d, the annular walls 114b, 114c, and the step 111c of upper chamber body 111 define an outer circular channel 116 configured for gas flow. The outer circular channel 116 is in fluid communication with the exhaust channels 117 in the upper chamber body 111.

A plurality of openings 114a (shown in FIG. 2) are formed through the annular wall 114c to allow fluid communication to the outer circular channel 116. In one embodiment, there may be equal numbers of opening 114a and exhaust channels 117, and the openings 114a and the exhaust channels 117 may be staggered to promote uniform flow. For example, each opening 114a may be positioned in between, or in the middle of, two neighboring exhaust channels 117.

A recess 114f is formed in the annular body 114d of the exhaust ring 114. As shown in FIG. 2, the showerhead liner 112 is disposed in the recess 114f of the exhaust ring 114 and supported by the exhaust ring 114. The showerhead liner 112 has an annular body 112a with a planar upper surface 112b for contacting the outer region of the showerhead surface 131a to prevent the showerhead plate 131 from contamination. The showerhead liner 112 has a circular wall 112c extending from the annular body 112a and in contact with the cover ring 113.

The cover ring 113 of upper liner assembly 118 is disposed radially inwardly of the exhaust ring 114 and below/under the showerhead liner 112. The cover ring 113 has an annular body 113e with a planar surface 113g for covering at least part of the step 111c of the upper chamber body 111. The outer diameter of the annular body 113e matches the inner diameter of the annular wall 114c of the exhaust ring 114 so that the step 111c is covered by the upper liner assembly 118.

The cover ring 113 has a circular wall 113f extending vertically upward from the annular body 113e. A plurality of spaced recesses 113c extend inwardly of the top of the circular wall 113f. The circular wall 112c of the showerhead liner 112 rests on the circular wall 113f of the cover ring 113. The cover ring 113, the showerhead liner 112, and the exhaust ring 114 define an inner circular channel 115 (FIG. 3B). The inner circular channel 115 is in fluid communication with the chamber enclosure 101 through the plurality of recesses 113c. In one embodiment, the recesses 113c are evenly distributed along the circumference of the circular wall 113f. The inner circular channel 115 is in fluid communication with the outer circular channel 116 via two or more openings 114a formed through the annular wall 114c of exhaust ring 114 (see FIG. 2).

The cover ring 113 also includes a lip 113a extending radially inwardly of the circular wall, adjacent to, but below, the inward terminus of the recesses 113c. The lip 113a circumscribes an opening 113d having a diameter d3. The diameter d3 is smaller than an outer diameter d4 of the substrate support 141. Thus, as shown in FIG. 3A, when the substrate support 141 is positioned in the upper substrate processing position, the lip 113a of the cover ring 113 and the substrate support 141 are positioned substantially close to one another without contacting each other, but, to form a labyrinth therebetween which enables fluid isolation between processing compartment 103 and loading compartment 102. At the upper substrate processing position, the substrate support 141 does not contact the lip 113a of the cover ring 113, so that the substrate support 141 can rotate about the central axis 155 during processing.

Optionally, as shown in FIG. 3A, one or more grooves 113b may be formed on a lower surface of the lip 113a to restrict the labyrinth formed between the substrate support 141 and the cover ring 113 to increase the isolation effect.

FIG. 3B shows another embodiment of the upper liner assembly 118 in relation to the showerhead assembly 130 and the upper chamber body 111. The showerhead liner 112 and the exhaust ring 114 shown in FIG. 3B are the same as those shown in FIG. 3A. However, unlike the embodiment of the upper liner assembly 118 shown in FIG. 3A, the cover ring 113 shown in the embodiment in FIG. 3B does not have a lip extending from circular wall 113f. The cover ring 113 has an annular body 113e with a planar surface 113g for covering at least a part of the step 111c of the upper chamber body 111. The cover ring 113 has a circular wall 113f extending vertically upward from the annular body 113e. The inside surface 113h of the circular wall 113f defines an opening having a diameter which may be a few millimeters larger than the outer diameter d4 of the substrate support 141. As shown in FIG. 3B, when the substrate support 141 is positioned in the upper substrate processing position, a narrow gap is formed between the circular wall 113f and the substrate support 141. The narrow gap allows the substrate support to rotate while maintaining fluid isolation between the processing compartment 103 and the loading compartment 102. The gap allows purge gas (e.g. nitrogen) in loading compartment 102 to exit the loading compartment 102 past the substrate support 141 t o keep process gases from the processing compartment 103 from entering loading compartment 102, thus maintaining fluid isolation.

FIG. 3C shows another embodiment of the upper liner assembly 118 in relation to the showerhead assembly 130 and the upper chamber body 111. The cover ring 113 and the exhaust ring 114 shown in FIG. 3C are the same as those shown in FIG. 3B. The showerhead liner 112 has an annular body 112a and a circular wall 112c extending down from the annular body 112a. An outer end of the annular body 112a extends between the cover ring 113 and the showerhead surface 131a and the circular wall 112c is inside of the cover ring 113. The showerhead liner 112 shown in FIG. 3C is configured to move vertically. The showerhead liner 112 in the embodiment shown in FIG. 3C has an inner step 112e formed by a bottom surface of the annular body 112a and a surface of the circular wall 112c facing the inside of the processing chamber, and an outer step 112f formed by the a bottom surface of the annular body 112a and the surface of the circular wall 112c facing the outside of the processing chamber. When the substrate support 141 is not in the upper substrate processing position, the annular body 112a of the showerhead liner 112 rests on the circular wall 113f of the cover ring 113, but when the substrate support 141 is in the upper substrate processing position, the annular body 112a is supported thereon and rotates therewith without interference with upper liner assembly 118.

As shown in FIG. 3C, when the substrate support 141 is in the upper substrate processing position, the inner step 112e covers an outside edge of the substrate carrier 104 that is not covered by the substrate 104a. This configuration helps maintain temperature uniformity across the substrate carrier 104 and prevents temperature non-uniformity edge effects near the edge of the substrate carrier 104 by moving the temperature non-uniformity edge effects to the annular body 112a of the showerhead liner 112.

As shown in FIG. 3C, when the substrate support 141 is positioned in the upper substrate processing position, a gap is formed between the showerhead liner 112 and the outer region of the showerhead surface 131a so that processing gases can exit processing compartment 103 and enter inner circular channel 115, as indicated by the arrows labeled A. A labyrinth is also formed between the outer step 112f and the circular wall 113f of the cover ring 113. The labyrinth allows the substrate support to rotate while maintaining fluid isolation between the processing compartment 103 and the loading compartment 102. The labyrinth also allows purge gas from loading compartment 102 to flow past the substrate support 141 into inner circular channel 115, as indicated by the arrows labeled B. The purge gas and the process gases combine inside inner circular channel 115, flow into outer circular channel 116 and flow though exhaust channels 117 out towards an exhaust (not shown) as indicated by the arrows labeled C, and process gas is restricted from reaching the region below the substrate support 141 where it would form deposits which could later flake off and contaminate substrates.

As shown in FIG. 3C, in one embodiment, an exhaust ring cover 180 may be disposed in the recess 114f of the exhaust ring 114 and supported by the exhaust ring 114. The exhaust ring cover 180 may have an annular body 180a and a circular wall 180c extending down from the annular body 180a. The annular body 180a has a planar upper surface 180b for contacting the outer region of the showerhead surface 131a. While the exhaust ring may be made of a material such as quartz, the exhaust ring cover 180 may be made of a material, such as silicon carbide, having a coefficient of thermal expansion close to that of the film being deposited in the processing chamber 100. This prevents flaking of deposited material from the exhaust ring during temperature changes in the chamber.

Referring to FIG. 2, the lower chamber body 121 may be an annular body having a slit valve opening 123a formed therethrough. The slit valve opening 123a is usually sized to interface with other chambers, such as a load lock chamber, a transfer chamber, or another processing chamber, in a cluster tool. Thus, the size of slit valve opening 123a may be limited by configurations of other chambers. The inner diameter of the lower chamber body 121 is substantially similar to the lower inner diameter d1 of the upper chamber body 111 so that the upper chamber body 111 is supported by the lower chamber body 121.

The lower liner 122 has an annular body with a slit valve opening 123b formed therethrough. The lower liner 122 has an outer diameter that matches the inner diameter of the lower chamber body 121 and the lower portion of the upper chamber body 111. The lower liner 122 is disposed inside the lower chamber body 121 and the lower portion of the upper chamber body 111 to shield the lower chamber body 121 and the upper chamber body 111 from the processing environment in the processing chamber 100. As shown in FIGS. 3A-3C, the planar surface 113g contacts an upper surface 122b of the lower liner 122 to form a complete liner over the upper chamber body 111. The slit valve opening 123b is positioned in alignment with the slit valve opening 123a of the lower chamber body 121.

Optionally, a lower exhaust path may be formed through the lower chamber body 121 and the lower liner 122 and connected to the vacuum pump 170 to provide additional pumping.

Upper chamber body 111 and lower chamber body 121 may be formed from a metal, such as stainless steel. The upper liner assembly 118 and the lower liner 122 may be formed from materials with low thermal conductivity and high resistance to chemical attack, such as quartz. In one embodiment, the upper liner assembly 118 and the lower liner 122 are formed from opaque quartz.

### Flow Path for Process Gases

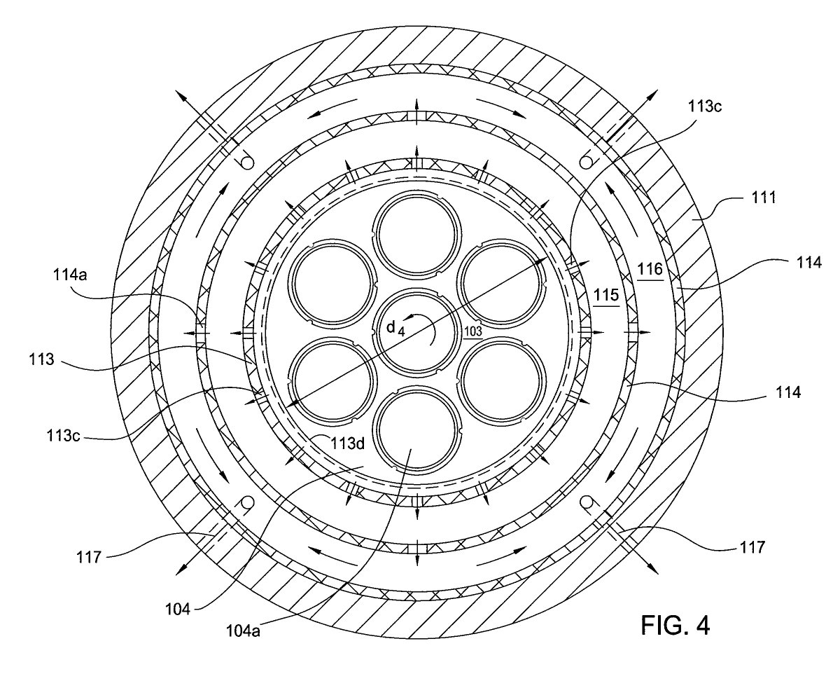

FIG. 4 is a top view of the processing chamber 100 without the showerhead assembly 130. FIG. 4 schematically illustrates the gas flow path in the processing chamber 100 during processing wherein cover ring 113, exhaust ring 114, and upper chamber body 111 are shown in section. The processing gases exit the processing compartment 103 of the chamber enclosure 101 from the plurality of recesses 113c and enter the inner circular channel 115. The processing gases then enter the outer circular channel 116 through the openings 114a, and eventually exit the processing chamber 100 through the exhaust channels 117 in the upper chamber body 111. In one embodiment, there are less openings 114a than the recesses 113c so that the process gases flow in tangential directions to extend the length of the exhaust path.

In addition to serving as a heat insulator and a contamination liner, the upper liner assembly 118 also forms exhaust paths for process gases. The circular channels 115, 116 provide a distance between the high temperature processing compartment 103 and the low temperature upper chamber body 111 and allow the temperature of the process gases to drop gradually when exiting the processing chamber 100. The gradual temperature drop allows process gases near the edge region of the substrate support 141 to have substantially the same temperature as the processing gas near the central region of the substrate support 141, thus, improving within chamber processing uniformity.

### Processing

During processing, the supporting shaft 142a lowers the substrate support 141 to the loading position as shown in FIG. 1A. No process gas is distributed from the showerhead assembly 130. The pin lifting shaft 143 then moves up to contact and lift the lifting pins 144. The lifting pins 144 extend above the top surface of the substrate support 141 allowing exchange of a substrate carrier 104 with an external robot. The slit valve door 123 opens so that the external robot can enter the chamber enclosure 101 to retrieve a substrate carrier from the lifting pins 144 and/or to drop off a substrate carrier with substrates to be processed on the lifting pins 144. When the external robot exits the chamber enclosure 101, the slit valve door 123 can be closed, and the pin lifting shaft 143 lowers the lifting pins 144 to the substrate support 141. Alternatively, instead of exchanging substrate carriers with the external robot, the lifting pins 144 can lift up individual substrates directly and exchange substrates with the external robot.

After the substrates are loaded on the substrate support 141, the supporting shaft 142a moves the substrate support 141 up to the upper substrate processing position as shown in FIG. 1B.

Referring to FIG. 3A, because the opening 113d formed by the lip 113a is smaller than the outer diameter of the substrate support 141, when positioned close to one another, the substrate support 141 and the cover ring 113 form a labyrinth which substantially isolates the chamber enclosure 101 into two sections: a loading compartment 102 and a processing compartment 103. The loading compartment 102 is defined by a back surface 141a of the substrate support 141, inner surface of the cover ring 113 under the lip 113a, inner surfaces 122a of the lower liner 122, and inner surfaces of the lower dome 151. The processing compartment 103 is defined by upper surfaces of the substrate carrier 104, and surfaces of substrates on the substrate carrier 104, the showerhead surface 131a, and inner surfaces of the upper liner assembly 118.

In the embodiment shown in FIG. 3B, the circular wall 113f and the substrate support 141 are positioned close to one another in the upper substrate processing position so that the substrate support 141 and the cover ring 113 form a narrow gap which substantially isolates the chamber enclosure 101 into two sections: a loading compartment 102 and a processing compartment 103. The loading compartment 102 is defined by a back surface 141a of the substrate support 141, inner surface of the cover ring 113, inner surfaces 122a of the lower liner 122, and inner surfaces of the lower dome 151. The processing compartment 103 is defined by upper surfaces of the substrate carrier 104, and surfaces of substrates on the substrate carrier 104, the showerhead surface 131a, and inner surfaces of the upper liner assembly 118.

In the embodiment shown in FIG. 3C, the showerhead liner 112 and the substrate support 141 are positioned close to the circular wall 113f in the upper substrate processing position to form a labyrinth so that the substrate support 141 substantially isolates the chamber enclosure 101 into two sections: a loading compartment 102 and a processing compartment 103. The loading compartment 102 is defined by a back surface 141a of the substrate support 141, inner surface of the cover ring 113, inner surfaces 122a of the lower liner 122, and inner surfaces of the lower dome 151. The processing compartment 103 is defined by upper surfaces of the substrate carrier 104, and surfaces of substrates on the substrate carrier 104, the showerhead surface 131a, and inner surfaces of the upper liner assembly 118.

Referring to FIG. 1B, the heating assembly 160 directs radiant energy towards the chamber enclosure 101 so that the substrates on the substrate support 141 reach the desired temperature. In the case of MOCVD, the substrates may be heated from about 450° C. to about 1100° C. Therefore, the chamber enclosure 101 is typically at a very high temperature. The upper chamber body 111 and the lower chamber body 121 stay at a lower temperature for energy conservation and for safety. The upper liner assembly 118 and the lower liner 122, made from material with low thermal conductivity, provide thermal insulation between the chamber enclosure 101 and the upper chamber body 111 and lower chamber body 121.

One problem typically created by temperature differences between the chamber enclosure 101 and the upper chamber body 111 and lower chamber body 121 is that the temperature near the edge region of the substrate support 141 is typically lower than the temperature near the central region of the substrate support 141. Therefore, there can be process non-uniformity between the edge region and the central region of the substrate support 141. Traditionally, to prevent non-uniformity near the edge region, a small substrate support is used to allow enough distance between the edge of the substrate support and the chamber body. This solution, however, limited the size of the effective processing area of the processing chamber.

Embodiments of the present invention provide a chamber body with an upper portion having a larger inner diameter than that of a lower portion. The larger inner diameter of the chamber body increases processing area of the processing chamber without increasing dimensions of other portions o f the chamber body. Therefore, embodiments of the present invention allow the substrate carrier 104 to have a diameter almost as large as the inner diameter of the loading compartment 102. Because the upper chamber body 111 has a portion with larger diameter than the lower chamber body 121, drastic temperature drop near the edge of the substrate carrier 104 can be prevented by exhausting the processing gases through the upper chamber body 111. The limitation of slit valve width may be overcome, i.e. reduced from the size of a multi-substrate carrier to the size/diameter of a substrate, by maintaining the substrate carrier 104 within the processing chamber 100 and loading/unloading substrates directly to/from the substrate carrier 104 in the chamber.

Particularly, as shown in FIG. 2, the upper portion of the upper chamber body 111 has an upper inner diameter d2 while the lower chamber body 121 and the lower portion of the upper chamber body 111 have a lower diameter d1 which is smaller than d2. The lower diameter dl and the upper inner diameter d2 may be determined by a distance necessary to avoid temperature drop near the edge of the substrate support 141 to obtain processing uniformity. For example, in one embodiment, when a substrate carrier is about 410 mm in diameter, the inner diameter of the lower liner 122 is slightly larger than that of the substrate carrier 104, the lower diameter d1 is similar to the outer diameter of the lower liner 122, and the upper inner diameter d2 of the upper chamber body 111 is about 578 mm. There is a distance of about 84 mm from the edge of the substrate carrier 104 to the inner surface of the upper chamber body 111 where the process gases can gradually cool off.

Process gases enter the processing compartment 103 from the showerhead plate 131. The process gases contact the substrates disposed on the substrate support 141 then exit the processing compartment 103 through the upper liner assembly 118 due to lower pressure in the exhaust channels 117 created by the vacuum pump 170. In one embodiment, the processing compartment 103 may be maintained at a pressure of about 760 Torr down to about 80 Torr for a MOCVD process.

Because the labyrinth formed between the cover ring 113 and the substrate support 141 isolates the loading compartment 102 from the processing compartment 103, the asymmetry created by the slit valve door 123 in the loading compartment 102 will have little effect on the gas flow in the processing compartment 103, thus improving processing uniformity. Therefore, the separation of the processing compartment 103 and the loading compartment 102 also increases processing uniformity. The slit valve opening 123b, facing the loading compartment 102, is not within the exit paths of the process gases during processing. The process gases can flow through the processing compartment 103 of the processing chamber 100 without the impact of the slit valve opening 123b. As shown in FIG. 4, paths for the processing gases in the processing compartment 103 can be symmetrical because structures of the upper chamber assembly 110 are symmetrical.

When processing is concluded, the flow of process gases ceases. The substrate support 141 lowers to the loading position as shown in FIG. 1A. The slit valve door 123 opens. The processed substrates can be unloaded and new substrates loaded for the next sequence.

The labyrinth formed between: the cover ring 113 and the substrate support 141 in the embodiment shown in FIG. 3A; the narrow gap formed between the cover ring 113 and the substrate support 141 in the embodiment shown in FIG. 3B; and the labyrinth formed between the cover ring 113, the showerhead liner 112, and the substrate support 141 in the embodiment shown in FIG. 3C in the processing position keeps most if not all process gases from entering the loading compartment 102. Therefore, surfaces defining the loading compartment 102 can remain uncontaminated for a period much longer than inner surfaces of the processing compartment 103. Structures surrounding the loading compartment 102 may be cleaned at a much lower frequency than the structures surrounding the processing compartment 103. Therefore, routine chamber cleaning procedure may include cleaning the upper chamber assembly 110 only.

In one embodiment, a periodic or routine chamber cleaning may comprise dismounting the showerhead assembly 130 to open up the processing chamber 100, replacing the dirty upper liner assembly 118 with a pre-cleaned upper liner assembly 118, and closing the processing chamber 100 to resume processing while cleaning the dirty upper liner assembly 118 off site. The cleaning procedure of the present invention minimizes chamber down time caused by cleaning, therefore, increases chamber efficiency and reduces cost of ownership.

### Retrofitting

Embodiments of the present invention can be used to retrofit existing processing chambers, particularly with processing chambers in a cluster tool. For example, the chamber body of an existing chamber can be used as the lower chamber assembly in the present application, so that that modified chamber can still interact with the remaining part of the processing system. A new upper chamber assembly 110 and a new showerhead assembly 130 can be placed over the existing chamber body. The new upper chamber assembly 110 provides a processing compartment with a larger diameter than the existing chamber body would. Therefore, more substrates can be processed in each batch. The new upper chamber assembly 110 also provides symmetrical exhaust paths that increase uniformity. Additionally, the separation of loading compartment and processing compartment prevents the existing chamber body from being contaminated. Periodic cleaning can be performed in the upper chamber assembly 110 alone.

In one embodiment, a lower exhaust path may be formed in the lower chamber assembly 120 and connected to the vacuum pump 170 for pumping out the loading compartment 102 when necessary. In the retrofitting scenario, the existing exhaust path can be used as the lower exhaust path.

### Advantages

Embodiments of the present invention provide several advantages over the traditional processing chamber. First, processing uniformity is improved because the slit valve opening, which typically causes the chamber to be asymmetric, is not in or along the paths of process gases. The slit valve opening is in the loading compartment. The process gases flow through the processing compartment which has a symmetrical flow path and is not in fluid communication with the loading compartment during processing.

Next, contamination or undesired deposition from processing gases is reduced due to compartmentalization. Because the processing gases do not go through the loading compartment, inner surfaces defining the loading compartment can remain clean for an extended period. Periodic cleaning is only needed for a portion of the processing chamber. Additionally, the configuration of the processing chamber of the present invention allows replacing elements of the upper chamber assembly with a precleaned set, thus greatly reducing chamber down time during cleaning.

Furthermore, embodiments of the present invention also improve productivity by providing an enlarged processing area with an upper chamber assembly having a larger inner diameter than that of a lower chamber assembly. For example, when the upper chamber assembly of the present invention is installed on an existing chamber, the modified chamber will have an increased processing area while other features, such as the slit valve door and the heating assembly, remain unchanged.

Even though a MOCVD chamber is described in the description above, processing chambers in accordance with the embodiments of the present invention can be used in any suitable process, such as hydride vapor phase epitaxy (HYPE), chemical vapor deposition, etching, and rapid thermal processing chamber.

While the foregoing is directed to embodiments of the present invention, other and further embodiments of the invention may be devised without departing from the basic scope thereof, and the scope thereof is determined by the claims that follow.

What is claimed is:

1. An apparatus for performing metal organic chemical vapor deposition (MOCVD), comprising:
a lower dome transparent to thermal energy;
a lower chamber assembly disposed over the lower dome, wherein the lower chamber assembly has a slit valve opening formed therethrough;
an upper chamber assembly disposed over the lower chamber assembly, wherein a symmetrical exhaust path is formed through the upper chamber assembly;
a showerhead assembly disposed over the upper chamber assembly, wherein the showerhead assembly, the lower chamber assembly, the upper chamber assembly and the lower dome define a chamber enclosure;
a heating assembly disposed outside the chamber enclosure and configured to transmit thermal energy to the chamber enclosure through the lower dome; and
a substrate support movably disposed in the chamber enclosure, wherein the upper chamber assembly has a lower inner diameter smaller than an outer diameter of the substrate support, the substrate support is movable between a lower loading position and an upper processing position, and the substrate support separates the chamber enclosure into a processing compartment and a loading compartment at the upper processing position.

2. The apparatus of claim 1, wherein the upper chamber assembly comprises:
an upper chamber body having a lower portion and an upper portion separated by a step, wherein two or more exhaust channels are symmetrically formed through the upper chamber body; and
an upper liner assembly removably disposed over the step.

3. The apparatus of claim 2, wherein the upper liner assembly comprises:
an exhaust ring disposed on the step of the upper chamber body;
a cover ring disposed radially inward of the exhaust ring; and
a showerhead liner disposed over the cover ring, wherein the cover ring, the showerhead liner and the exhaust ring define an inner circular channel surrounding and connected to the processing compartment, the exhaust ring and the upper chamber body define an outer circular channel surrounding the inner circular channel, and the outer circular channel is fluidly connected to the inner circular channel and the two or more exhaust channels in the upper chamber body.

4. The apparatus of claim 3, wherein the cover ring comprises a lip extending radially inward, the lip has an inner diameter smaller than an outer diameter of the substrate support, the lip of the cover ring and the substrate support form a labyrinth when the substrate support is in the upper processing position, and the labyrinth prevents processing gases in the processing compartment from entering the loading compartment.

5. The apparatus of claim 3, wherein the showerhead liner comprises an inner lip extending radially inward, the showerhead liner is vertically movable between the showerhead and the substrate support, the inner lip has an inner diameter smaller than an outer diameter of the substrate support, the inner lip rests on a substrate carrier on the substrate support when the substrate support is in the upper processing position, the showerhead liner comprises an outer lip extending radially outward, the outer lip of the showerhead liner and the substrate support form a labyrinth when the substrate support is in the upper processing position and the labyrinth substantially prevents processing gases in the processing compartment from entering the loading compartment.

6. The apparatus of claim 3, wherein the cover ring has a plurality of first openings evenly distributed along the cover ring, and the plurality of first openings provide fluid communication between the processing compartment and the inner circular channel.

7. The apparatus of claim 6, wherein the exhaust ring has two or more second openings evenly distributed along the exhaust ring, the second openings provide fluid communication between the inner circular channel and the outer circular channel, the number of the second opening equals the number of the exhaust channels in the upper chamber body, and the second openings and the exhaust channels are staggered.

8. The apparatus of claim 3, wherein the cover ring, the showerhead liner and the exhaust ring are formed from opaque quartz.

9. The apparatus of claim 2, wherein the lower chamber assembly comprises:
a lower chamber body; and
a lower liner disposed inside the lower chamber body, wherein the slit valve door opening is formed through the lower chamber body and the lower liner.

10. An apparatus comprising:
a lower chamber body surrounding a loading compartment of a chamber enclosure, wherein a slit valve door opening is formed through the lower chamber body;
an upper chamber body disposed over the lower chamber body, wherein the upper chamber body surrounds a processing compartment of the chamber enclosure, two or more exhaust channels are formed through the upper chamber body, and the two or more exhaust channels are evenly distributed along the upper chamber body;
a showerhead assembly disposed over the upper chamber body; and
a substrate support disposed in the chamber enclosure, wherein the processing compartment has a lower inner diameter smaller than an outer diameter of the substrate support, the substrate support is movable between a lower loading position and an upper processing position, and the substrate support substantially prevents fluid communication between the loading compartment and the processing compartment at the upper processing position.

11. The apparatus of claim 10, wherein the upper chamber body has a lower portion and an upper portion separated by a step, the lower portion has a first inner diameter, the upper portion has a second inner diameter, and the second inner diameter is larger than the first inner diameter.

12. The apparatus of claim 11, further comprising an upper liner assembly removably disposed over the step of the upper chamber body, wherein the upper liner assembly defines exhaust paths connecting the processing compartment to the two or more exhaust channels in the upper chamber body.

13. The apparatus of claim 12, wherein the upper liner assembly comprises:
an exhaust ring;
a cover ring disposed radially inward of the exhaust ring; and
a showerhead liner disposed over the cover ring, wherein the cover ring, the showerhead liner and the exhaust ring define an inner circular channel surrounding and connected to the processing compartment, and the exhaust ring and the upper chamber body define an outer circular channel surrounding the inner circular channel, and the outer circular channel are fluidly connected to the inner circular channel and the two or more exhaust channels in the upper chamber body.

14. The apparatus of claim 13, wherein the cover ring comprises a lip extending radially inward, the lip has an inner diameter smaller than an outer diameter of the substrate support, the lip of the cover ring and the substrate support form a labyrinth when the substrate support is in the upper processing position, and the labyrinth substantially prevents processing gases in the processing compartment from entering the loading compartment.

15. The apparatus of claim 13, wherein the showerhead liner comprises an inner lip extending radially inward, the showerhead liner is vertically movable between the showerhead and the substrate support, the inner lip has an inner diameter smaller than an outer diameter of the substrate support, the inner lip rests on a substrate carrier on the substrate support when the substrate support is in the upper processing position, the showerhead liner comprises an outer lip extending radially outward, the outer lip of the showerhead liner and the substrate support form a labyrinth when the substrate support is in the upper processing position and the labyrinth substantially prevents processing gases in the processing compartment from entering the loading compartment.

16. The apparatus of claim 13, wherein the cover ring has a plurality of first openings evenly distributed along the cover ring, and the plurality of first openings provide fluid communication between the processing compartment and the inner circular channel.

17. The apparatus of claim 16, wherein the exhaust ring has two or more second openings evenly distributed along the exhaust ring, the second openings provide fluid communication between the inner circular channel and the outer circular channel, the number of the second opening equals the number of the exhaust channels in the upper chamber body, and the second openings and the exhaust channels are staggered.

18. The apparatus of claim 13, wherein the cover ring, the showerhead liner and the exhaust ring are formed from opaque quartz.

19. The apparatus of claim 12, further comprising a lower liner disposed inside the lower chamber body, wherein the slit valve door opening is formed through the lower chamber body and the lower liner.

20. A processing kit, comprising:
an upper liner assembly defining a symmetrical fluid path; and
a lower liner having a slit valve door opening formed therethrough.

21. The processing kit of claim 20, wherein the upper liner assembly comprises:
an exhaust ring;
a cover ring disposed radially inward of the exhaust ring; and
a showerhead liner disposed over the cover ring, wherein the cover ring, the showerhead liner and the exhaust ring define an inner circular channel in fluid communication with a region radially inward of the upper liner assembly, the exhaust ring defines an outer circular channel surrounding the inner circular channel, and the outer circular channel is fluidly connected to the inner circular channel.

22. The processing kit of claim 20, wherein the cover ring comprises a lip extending radially inward, the lip is configured to form a labyrinth with a substrate support in a processing chamber.

23. A method for forming metal nitride films using a processing chamber, comprising:
loading one or more substrates to a substrate support of the processing chamber through a slit valve opening formed through a lower chamber body of the processing chamber, wherein the substrate support is in a loading position during loading the one or more substrates;
moving the substrate support from the loading position upwards to a processing position, wherein the substrate support in the processing position and an inner opening of an upper liner assembly separate an inner volume of the processing chamber into a processing compartment above the substrate support in the processing position and a loading compartment below the substrate support in the processing position, and isolate the processing compartment and the loading compartment to substantially prevent fluid communication between the processing compartment and the loading compartment;
flowing a processing gas comprising a metal containing precursor and a nitrogen containing precursor to form a metal nitride film on the one or more substrates while exhausting the processing gas through the upper liner assembly and exhaust paths formed through an upper chamber body coupled to the lower chamber body;
ceasing the flow of the processing gas;
lowering the substrate support to the loading position; and
unloading the one or more substrates from the processing chamber through the slit valve opening.

24. The method of claim 23, further comprising:
repeating the loading, moving, flowing, ceasing, lowering and unloading for multiple batches of substrates; and
performing a routine chamber cleaning comprising:
removing the upper liner assembly;
placing a pre-cleaned upper liner assembly in the processing chamber; and
resuming processing with the pre-cleaned upper liner assembly.

25. The method of claim 24, further comprising cleaning the removed upper liner assembly away from the processing chamber.
